(19) United States
(12) Patent Application Publication
(10) Pub. No.: US 2011/0197968 A1
(43) Pub. Date: Aug. 18, 2011

(54) SOLAR COLLECTOR PANEL

(76) Inventor: Derek Montgomery, Mendoza (AR)

(21) Appl. No.: 12/737,484

(22) PCT Filed: Aug. 14, 2009
(86) PCT No.: PCT/US2009/004668

§ 371 Date: Apr. 27, 2011

Related U.S. Application Data
(60) Provisional application No. 61/189,092, filed on Aug. 16, 2008.
(60) Provisional application No. 61/210,781, filed on Mar. 23, 2009.

(51) Int. Cl. H01L 31/0232

(52) U.S. Cl. 136/259

(57) ABSTRACT

A solar deflecting assembly for significantly improving the efficiency of solar collection panels. The assembly is easy to manufacture and can be operated in a passive mode. The assembly is especially effective for bi-facial solar panels or for thin film solar photoreceptors deployed around cylinders.

### CROSS REFERENCE TO RELATED APPLICATIONS

This application claims the benefits of U.S. provisional Ser. Nos. 61/189,092 filed on Aug. 16, 2008 and 61/210,781 filed Mar. 23, 2009.

### FIELD OF THE INVENTION

The present invention relates to solar energy conversion systems and methods to collect, redirect, and concentrate sunlight to enhance the efficiency of energy production.

### BACKGROUND OF THE INVENTION

There are two main classes of solar energy conversion systems, thermal and photovoltaic. Thermal systems use a thermal transfer medium, such as water to absorb heat from solar radiation, and require a secondary generator to convert the heat into electrical power. Photovoltaic systems generate electrical current directly, and most commonly are comprised of arrays of photodiodes cells made from silicon. Because photovoltaic cells produce electricity directly, they are suitable for both small and large installations and the electrical power can be easily connected to the distribution grid. Thermal systems can be used to heat water on a small scale, but typically are only suitable for large installations for power generation because of the need to convert to electricity using a secondary generator.

Despite impressive improvements in efficiency in the past 30 years, the main drawback of photovoltaic systems is the high cost of silicon photocells. Intending to lower costs, the prior art includes many examples of optical concentrators that capture sunlight from a large aperture, using less expensive materials such as Fresnel lenses and curved mirrors, and focus the light on to a smaller photocell surface. Although the concentration factors can be impressive, focusing optics introduce other problems that are difficult and costly to overcome. There is generally a trade off between the field of view and the concentration factor, which means that high magnification concentrator systems need to incorporate mechanical tracking systems to follow the sun's movement. Furthermore, many such concentrator systems require a specialized form factor of solar cells which makes these systems difficult to integrate with commercially available large format photovoltaic panels.

The prior art also includes a number of examples of sunlight collector systems that do not involve tracking mechanisms, but instead have a wide field of view for capturing sunlight as the sun moves across the sky. In general, they do not concentrate the sunlight to the same extent as systems which track the sun, but are desirable because of the inherent simplicity of a system with no moving parts. However, many of the non-tracking collector systems described in the prior art also require specialized form factors and are not suitable for use with large format solar panels.

In an attempt to further improve the efficiency of photovoltaic solar panels, several companies have developed or have announced they are developing so-called bifacial solar cells that can be illuminated from both sides, including Hitachi, Sanyo, Gamma Solar, Sun Power Corporation, and Origen Energy. Bifacial solar cells can be mounted vertically to receive sunlight directly on the side facing the sun as well as albedo sunlight reflected from the surrounding terrain on the reverse side. Reportedly, the solar collection efficiency can be boosted by as much as 35% compared to a single-sided panel in such a configuration, but the benefit depends on the terrain of the particular installation and the proximity of other panels if a number of them are arranged in a collection array.

Sunlight deflecting panels have also been used to reduce glare by reflecting the sunlight entering buildings at a relatively steep vertical angle towards the ceiling, while allowing light passing horizontally to transmit directly to allow a viewer to see through the window. Although these panels have been demonstrated to be effective for building lighting management, it is not clear if they would be suitable for solar energy applications or how to optimize them accordingly.

Gellert (U.S. Pat. No. 4,074,704) describes the use of a lenticular vertical panel comprised of an array of elongated prisms combined with reflector panels used to capture sunlight at low angles in winter for the purpose of heating a fluid in a pipe, but the system has a limited field of view and does not work efficiently when the sun is higher in the sky.

Butler (U.S. Pat. No. 4,513,734) describes a system of simple plane mirrors used to reflect light on to both sides of a bifacial flat plate photoreceptor, which receives sunlight over a wide field of view, but the efficiency of the collecting aperture is very low. Another example is described by Finkl (U.S. Pat. No. 5,538,563), using simple flat reflectors, but the field of view is restricted and it requires a tracking mechanism to maintain efficiency.

There are a number of examples of transparent panels intended for vertical building windows that incorporate arrays of horizontal reflecting surfaces to reflect overhead sunlight on to the ceiling to prevent glaring sunlight from entering directly while allowing viewers to look through at a near horizontal angle. None of these inventions includes a description of how the panels may be used for the purpose of efficient solar energy conversion, but are relevant because they describe sunlight deflector panels with similar construction to the present invention. Wadsworth describes a transparent panel with thin slots that reflect light by total internal reflection, but the width and draft of the slots would create significant scatter and losses for solar power collection applications. Milner describes an alternative design incorporating two panels with interlocking ridges which could reduce the width of the air gaps to insignificant dimensions.

Thus there is a need for a low cost and effective solar deflecting system to direct the sun's rays efficiently onto conventional large format photovoltaic panels.

### SUMMARY OF THE INVENTION

This need is met by a solar deflector panel assembly for directing sunlight on to a photoreceptor surface including at least an approximately rectangular solar deflector panel constructed of a transparent material having a length L, a width W, a top surface, a bottom surface, and an inner and outer edge along length L; an array of spaced planar reflecting surfaces extending over the length L of the solar deflector panel substantially parallel to the inner and outer edges, the planer reflecting surfaces being substantially perpendicular to the top and bottom surfaces; an approximately rectangular photoreceptor surface having a top edge and a bottom edge positioned so the top edge of the photoreceptor surface is oriented towards the sky and the bottom edge oriented towards the ground; and wherein the solar deflector panel, is positioned so that the inner edge is held in proximity and approximately level with the top edge of the photoreceptor surface and the outer edge of the solar deflector panel is extended away from the photoreceptor surface.

Another aspect is a solar deflector panel as described above, wherein the solar deflector panel is constructed of a stack of identical elongated strips of transparent material, each strip with parallel top and bottom surfaces and two opposing parallel reflective side surfaces substantially perpendicular to the top and bottom surface, affixed together with the top and bottom surfaces of the elongated strips forming flat top and bottom surfaces of the deflector panel.

Another aspect is a solar deflector panel and photo receptor surface as described wherein the array of reflecting surfaces are tilted with respect to the surface normal of the top and bottom deflector panel surfaces.

Another aspect is a solar deflector panel as described wherein the reflective surfaces are composed of metallic or dielectric coatings.

Another aspect is a solar deflector panel as described wherein the transparent material has a refractive index of greater than 1.414 and the reflecting surfaces are achieved by total internal reflection by providing a small gap between the reflecting. surfaces.

Another aspect is a solar deflector panel as described, wherein separate top and/or bottom sheets of transparent material are laminated and affixed to the stack of the elongated strips.

Another aspect is a solar collection assembly including at least the solar deflector panel described above, and an additional rectangular reflector panel fit between the bottom edge of the photoreceptor surface and the outer edge of the solar deflector panel.

Another aspect is a solar deflector panel and photoreceptor surface as described, wherein the photoreceptor surface is bifacial and an additional solar deflector panel is disposed on the opposite side of the photoreceptor surface.

Another aspect is a solar deflector panel and photoreceptor surface as described wherein the photoreceptor surface is bifacial and an additional solar deflector panel and an additional rectangular reflector panel is disposed on the opposite side of the photoreceptor surface.

Another aspect is a solar deflector panel as described, wherein the solar deflector panel is comprised of a stack of identical elongated strips of transparent material, each strip with parallel top and bottom surfaces and two opposing parallel reflective side surfaces tilted with respect to the surface normal's of the top and bottom surfaces, affixed together with the top and bottom surfaces of the elongated strips forming flat top and bottom surfaces of the deflector panel.

Another aspect is a solar deflector panel and photoreceptor surface as described, wherein the photoreceptor surface is bifacial and an additional solar deflector panel is disposed on the opposite side of the photoreceptor surface.

Another aspect is a solar deflector/reflector panel and photoreceptor surface as described wherein the photoreceptor surface is bifacial and an additional solar deflector panel and an additional rectangular reflector panel is disposed on the opposite side of the photoreceptor surface.

Another aspect is a solar deflector/reflector panel configuration and photoreceptor surface wherein the photoreceptor surface is deployed around one or more cylinders configured within a solar deflector/reflector configuration such as shown in FIG. 18.

The present invention involves the use of a thin solar deflector panel to direct sunlight on to a photoreceptor surface such as a photovoltaic solar panel. The photovoltaic panel is held on edge as compared to conventional panels that are generally laid flat facing the sky. The solar deflector is extended outward from the top edge of the photovoltaic panel to present a large collection aperture to the sun, and either transmits or reflects incident sunlight on to the photovoltaic panel. Two deflector panels can be placed on opposite sides of the photovoltaic panel and therefore the present invention is suitable for use with bifacial solar cells. In addition to the solar deflector panel, a secondary reflector panel may also be incorporated into the system to enhance the collection efficiency further, positioned with one edge proximal to the bottom edge of the solar cell panel and the other edge in close contact with the outer edge of the solar deflector panel.

The solar deflector panel is comprised of a transparent material with an embedded array of evenly spaced planar reflecting surfaces, approximately perpendicular to the top and bottom surfaces of the deflector panel, and extending over its length. The panel may be constructed of a stack of identical elongated strips, with rectangular or parallelogram cross-sections, and planar reflecting surfaces at the boundary between each strip. Sunlight is both reflected by the reflecting surfaces and transmitted through the transparent material without deviation, depending on the angle of the incident sunlight. The proportion of light that is reflected or transmitted without deviation varies as the sun moves across the sky such that an optimal amount of light is directed at the photoreceptor.

The aspect ratio of the rectangular cross section of the elongated strips, defined as the ratio of the width divided by the height, can be adjusted to optimize the solar collection efficiency over a very wide field of view and therefore does not need tracking mechanisms to operate effectively. This also means that diffuse light can be captured efficiently, which is particularly important when there is significant obscuration of direct sunlight due to cloud cover. The aspect ratio can be optimized to provide uniform collection efficiency over a wide range of sun angles, or alternatively optimized to produce greater efficiency when the sun is either high in the sky or low in the sky.

In another preferred embodiment, the elongated reflective strips are tilted towards the sky that concentrates the sunlight upon reflection when the sun is high in the sky, at the sacrifice of efficiency when the sun is lower in the sky. In this configuration, concentration factors of up to 7× can be achieved over relatively small fields of view. Such a system would be suitable for use with a mechanical tracking mechanism that follows the sun's movement during the day.

The performance of the deflector panel relies solely on the relative geometry of the deflecting strips and therefore can be scaled to whatever thickness of panel is desired. Thin lightweight panels can be constructed by shrinking the geometry of the deflector strip cross sections, or thicker and more robust panels can be constructed accordingly by making the strip cross sections larger.

It is therefore an object of the invention to provide a thin and lightweight solar deflector panel, constructed of inexpensive materials, which is easy to install and maintain and which can be scaled to large dimensions suitable for use with large format photovoltaic panels.

It is a further object of the invention to provide a solar deflector panel optimized to collect light over a large field of view so that no tracking mechanisms are required. Accordingly, the invention would be suitable for collection of diffuse sunlight. It is a further object of the invention to provide a solar deflector optimized to concentrate the sunlight on to a photoreceptor surface to improve the collection efficiency over a relatively narrow field of view.

It is yet another object of the invention to provide a solar deflector panel which is optimized for use with bifacial photovoltaic panels.

It is a further object of the invention to provide a solar deflector panel that is optimized for use with cylindrical photovoltaic panels.

### BRIEF DESCRIPTION OF THE DRAWINGS

FIG. 1 is a view of the solar deflector panel of the invention.

FIG. 2 is a view of one aspect of the solar collection assembly of the invention.

FIG. 3 is a rectangular cross section of one of the strips of the deflector panel.

FIG. 4 is a graph of solar collection efficiency.

FIG. 5 is a graph of solar collection efficiency.

FIG. 6 is a graph of solar collection efficiency.

FIG. 7 is a graph of solar collection efficiency.

FIG. 8 is a rectangular cross section of one of the strips of the deflector panel.

FIG. 9 is a graph of solar collection efficiency.

FIG. 10 is an alternate view of the solar collection assembly of the invention.

FIG. 11 is a graph of solar collection efficiency.

FIG. 12 is a graph of solar collection efficiency.

FIG. 13 is a graph of solar collection efficiency.

FIG. 14 is a view of a possible configuration of a deflector panel.

FIG. 15 is alternate views of deflector panels.

FIG. 16 is a view of one aspect of the solar collection assembly of the invention.

FIG. 17 is a view of embodiments utilizing curved deflector or reflector panels.

FIG. 18 is a view of embodiments using cylindrical shaped photoreceptors.

FIG. 19 is a view of a possible aspect of the solar collection assembly of the invention.

FIG. 20 is a view of a possible aspect of the solar collection assembly of the invention.

FIG. 21 is a view of a possible aspect of the solar collection assembly of the invention.

FIG. 22 is a graph of solar collection efficiency.

FIG. 23 is an alternate view of the solar collection assembly of the invention.

FIG. 24 is an alternate aspect of the solar deflector panel of the invention.

FIG. 25 is an alternate aspect of the solar collection assembly of the invention.

FIG. 26 is an alternate aspect of the solar collection assembly of the invention.

FIG. 27 is a graph of solar collection efficiency.

FIG. 28 is a graph of solar collection efficiency.

### DESCRIPTION OF THE PREFERRED EMBODIMENTS

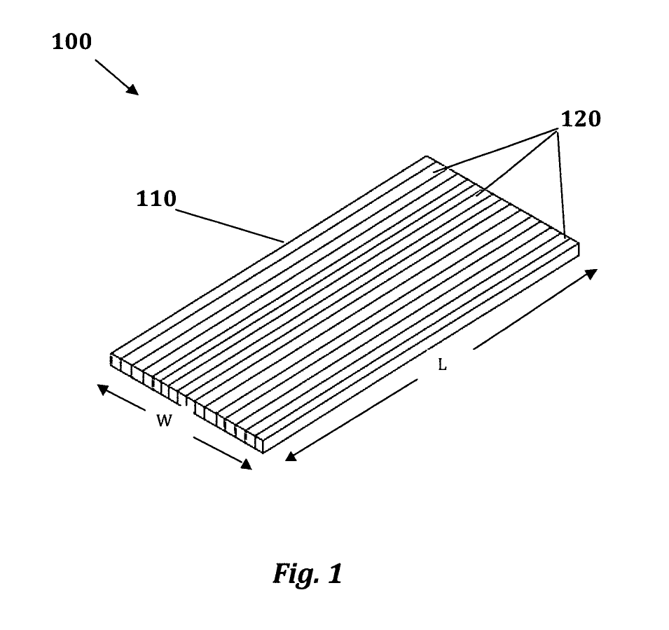

FIG. 1, shown generally as the numeral 100, is a solar deflector panel of the present invention. The solar deflector panel 110 is comprised of an array of identical elongated strips 120 with a rectangular cross-section, composed of a transparent material such as glass or clear plastic and affixed together to form a continuous sheet with flat top and bottom surfaces. The sides of each rectangular strip are reflective, either by coating the surface with a mirror such as silver or by total internal reflection by introducing a small gap between strips. Other possible coatings are metallic or dielectric. Scaling the dimensions of the rectangular strip cross-sections can scale solar deflector panel 110 to any desired width W, by adding more strips, and to any desired length L, to suit a particular application, and to any desired thickness.

Solar deflector panel 110 thus contains a set spaced planar reflecting surfaces extending over the length L of the panel. The solar deflector panel shown in FIG. 1 has a rectangular shape as that is a preferred embodiment. Rectangular is preferred because most photoreceptor panels are rectangular. But some variation from a pure rectangular shape is possible and the invention anticipates all of these. Accordingly the term approximately rectangular is often used in this description and in the claims in recognition of some variation from pure rectangularity. The spaced planer reflecting surfaces described are in a preferred embodiment parallel to the outer edges of panel 110 and perpendicular to the top and bottom surfaces of panel 110 but it is recognized that some deviation fro pure parallel and pure perpendicular are possible in such a deflector panel and this invention anticipates those possibilities. Accordingly the terms substantially parallel and substantially perpendicular are used in this description.

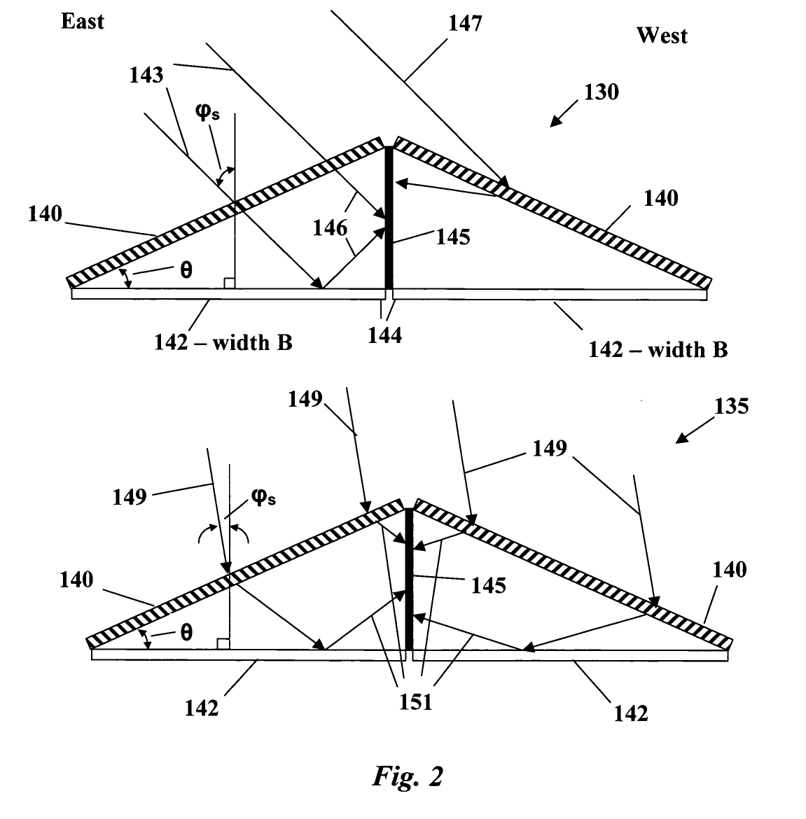

Referring now to FIG. 2, a preferred embodiment is shown generally by the numeral 130, as an assembly comprised of two solar deflector panels 140, two plane reflector panels 142 of length B and a single bifacial photoreceptor panel 145. For the purpose of facilitating the description of the present invention, the sun will be presumed to be passing directly overhead from due east to due west. Numeral 135 is another view of the same embodiment at a different time of day and therefore with different sun angles. The photoreceptor panel 145 is oriented vertically and aligned parallel to the north south axis and therefore has an eastern side and a western side and a top and bottom edge. The two reflector panels 142 are oriented horizontally with an inner edge 144 in close contact with both sides of the bottom edge of the photoreceptor panel 145. The two solar deflector panels 140 are connected to the open ends of the photoreceptor panel 145 and the reflector panels 142 to form two back-to-back identical right angle triangles. The angle between the deflector panels 140 and the corresponding reflector panel 142 is defined as θ. The width of the collection aperture of the entire assembly is 2B, equal to the width of the two reflector panels 142, each of width B.

The sunlight is incident on the deflector panels 140 at varying angles throughout the day as the sun traverses the sky, from east to west shown as left to right in numerals 130 and 135. Numeral 130 shows the rays of light from the sun when it is low in the sky during the early morning. A majority of the sunlight is incident upon the eastern solar deflector panel, which transmits a preferentially high amount of the incident light without deviation, indicated by rays 143. These transmitted rays subsequently impinge upon the eastern side of the photoreceptor 145, either directly or upon reflection from the bottom reflector panel, as shown by rays 146. The remaining sunlight 147 incident on the western deflector panel reflects a preferentially high amount of the incident light back towards the western side of the bifacial photoreceptor surface 145. It is obvious with such a symmetric geometry that the same description holds for incident rays during the late afternoon, except that the preferential rays are reversed and the majority of the solar rays are transmitted through the western deflector panel and reflected by the eastern panel, on to the respective sides of the photoreceptor panel.

Numeral 135 of FIG. 2 shows incident rays 149 when the sun is high in the sky during mid-day. The light rays incident on the east and west deflector panels are preferentially reflected towards the respective east and west photoreceptor surfaces of 145 either directly or upon reflection from the bottom reflectors 142 as indicated by rays 151.

To further understand the operation of the deflector panel assembly and how to optimize its performance, the following analysis is provided. Referring again to FIG. 2, the proportion of sunlight relative to the solar luminance level which is incident on the collection aperture 2B is:

η_{A}=cos φₛ 1.

where φₛ is the angle of incidence of the sun relative to the ground normal.

Furthermore, the proportion of the sunlight incident on the collecting aperture 2B which impinges on the eastern deflector panel is determined by the following equations:

ηᵢ=½(1+tan θ·tan φₛ); for |φₛ|≦90 −θ 2a.

ηᵢ=2/(1+tan θ·tan φₛ); for φₛ>90−θ 2b.

θᵢ=0; for φₛ<−(90−θ) 2c.

where θ is the angle of inclination of the deflector panel 140 relative to the surface of the ground.

Referring again to FIG. 2, the proportion of light which passes through the eastern deflector panel, and is incident directly on the eastern side of photoreceptor panel 145 is determined by the following equations:

η_{d}=(sin φₒ·sin θ)/sin(90+θ−φₒ); for φₒ>0 3a.

η_{d}=0; for φₒ≦0 3b.

where φₒ is the angle of incidence relative to the ground normal of a ray that exits from the eastern deflector panel with or without deviation.

Furthermore, the proportion of light that passes through the eastern deflector panel and is reflected by the bottom reflector onto the photoreceptor surface is determined by the following equations:

ηₘ=η_{d}; for n_{d}≦0.5 4a.

ηₘ=1−η_{d}; for n_{d}>0.5 4b.

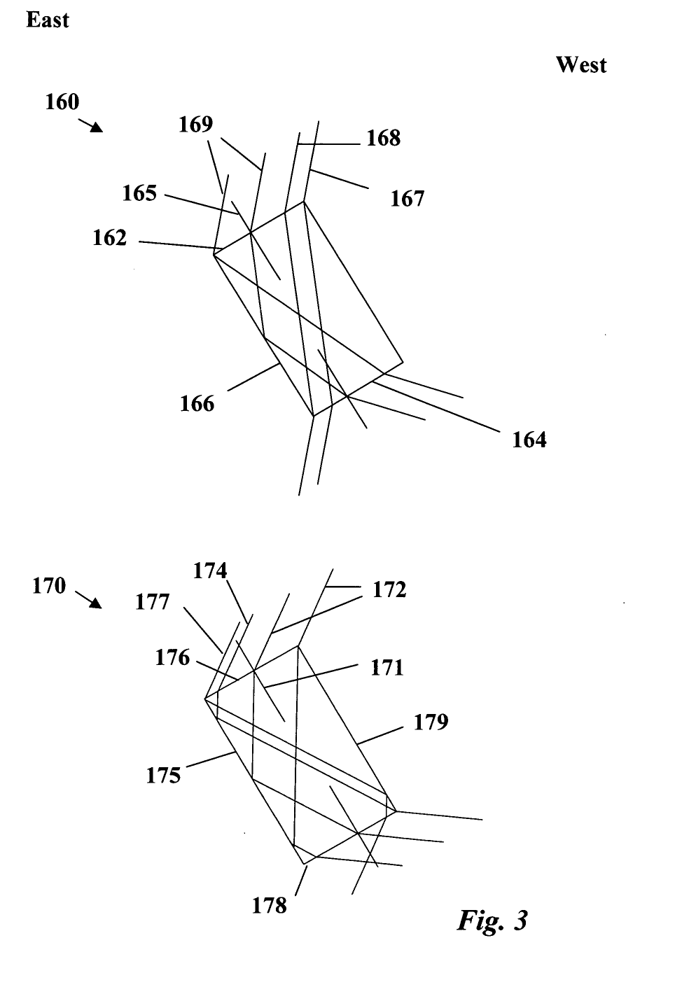

Referring now to FIG. 3, the rectangular cross section of one of the deflector panel strips is shown generally by the numeral 160, with several ray traces of sunlight incident on the top entrance face 162. Starting with ray 167 at the extreme western edge of the rectangular strip entrance face, the ray undergoes a refractive deviation at the entrance face 162 and a second refractive deviation on the exit face 164, without impinging on the reflective side face 166. The second ray 168 closest to the western edge of the rectangular strip is shown to go through similar refractive deviations and exits at the eastern edge of the exit face 164, and therefore represents the extreme ray which passes through without reflection. Incident rays 167 and 168 are shown to pass through the panel without angular deviation because the top and bottom panel surfaces are parallel. The next two incident rays 169 are shown to undergo a refractive deviation on the entrance face 162, a reflection from the eastern side face 166, and subsequently a second refractive deviation at the exit face 164.

The proportion of the sunlight incident on the entrance face which passes through the rectangular strip without reflection is determined by the following equation:

ηₜ=(w−|tan φ^{rr}|)/w; for |tan φ^{rr}|≦w 5a.

ηₜ=0; for |tan φᵣᵣ|>w 5b.

where w is the width of the rectangular strip relative to the thickness of the glass panel t, and w/t is the aspect ratio, and φᵣᵣ is the angle of the refracted ray relative to the panel surface normal 165.

The angle of the refracted beam can be calculated from Snell's law, as follows:

φᵢ=φₛ+θ 6.

where φᵢ is the angle of the incident ray relative to the panel surface normal 165. It follows that:

φᵣᵣ=arcsin(sin φᵢ/n) 7.

where n is the refractive index of the transmitting medium.

The numeral 170 in FIG. 3 shows a similar deflector panel strip in cross-section with sunlight rays now incident at a greater angle relative to the panel surface normal 171. Rays 172 are shown to undergo a refractive deviation at the entrance face 176 and then a reflection on the eastern side 175 of the rectangular strip and another refractive deviation on exit face 178. It is noted that the angle of incidence is equal to the angle of exit relative to the respective top and bottom panel surfaces 176 and 178. Ray 174 is also shown to go through similar deviations and exits at the western edge of exit face 178, and therefore represents the extreme ray that passes through with a single reflection. Finally, ray 177 is shown to go through a similar refractive deviation at entrance face 176 and reflection at the eastern side 175, but it also reflects off of the opposite western side 179 of the rectangular strip. The proportion of the sunlight incident on the entrance face of the rectangular strip that undergoes a single reflection is determined by the following equations:

ηᵣ=1−ηₜ; for tan φᵣᵣ≦w 8a.

ηᵣ=(w/tan φᵣᵣ)−ηₜ; for tan φᵣᵣ>w 8b.

The angle of the exiting reflected ray can be determined again from Snell's Law:

φ_{rf}=φᵣᵣ 9.

φᵣₒ=arcsin(n·sin φ_{rf}) 10.

φ_{R}=φᵣₒ+θ 11.

where, φ_{rf} is the angle of incidence of the reflected ray relative to the panel surface normal; φᵣₒ is the angle of the exiting reflecting ray relative to the panel surface normal; and φ_{R} is the angle of the reflected ray exiting the panel relative to the ground normal.

The proportion of the light incident on the eastern panel that undergoes a single reflection, and is incident directly or by reflection from the bottom reflector surface on the eastern side of the photoreceptor panel is determined by substituting φ_{R} for φₒ in equations 4 through 7.

It follows that the total proportion of sunlight which passes through the eastern deflector panel, either without deviation or by a single reflection, and is incident on the eastern side of the photoreceptor surface either directly or by reflection from the bottom reflector, is determined by the following equation:

η_{E}=η_{A}·ηᵢ·(ηₜ(η_{dt}+ηₘₜ)+ηᵣ(η_{dr}+ηₘᵣ)) 12.

where, η_{dt}, ηₘₜ, η_{dr}, ηₘᵣ are respectively the relative proportions of light that are transmitted directly, transmitted and then reflected off the bottom mirror, reflected directly, and reflected and then reflected from the bottom mirror.

It also follows from the obvious symmetry of the geometry that a similar set of equations can be obtained for the western side panel and the total amount of light collected by both sides is the sum of the two. Therefore

η_{w}(φₛ)=η_{E}(−φₛ); and 13.

η_{T}(φₛ)=η_{W}(φₛ)+η_{E}(φₛ) 14.

where η_{T} is the total efficiency collected by the east and west panels.

The total amount of sunlight collected in the day is normalized by the following equation:

N_{eff}=2·B·Σ η_{T}(φₛ)/Σ cos(φₛ) 15.

where N_{eff} is the normalized total integrated daily sunlight collected, expressed in the relative number of single sided panels lying horizontally on the ground.

Equations 1 through 15 can be solved for any combination of the parametric variables η, w, and n, as a function of the solar angle φₛ, to determine the proportion of sunlight incident on the collection aperture that is directed on to both sides of the photoreceptor surface.

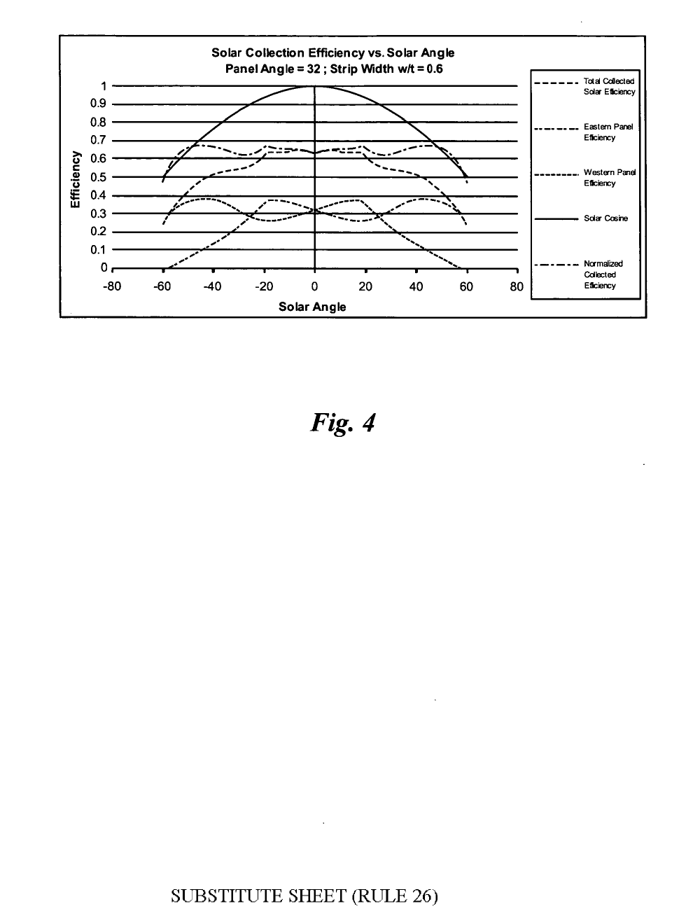

FIGS. 4, 5, and 6 show three solutions to the set of equations. FIG. 4 shows a graph of the solar collection efficiency as a function of solar angle for η=32° and an aspect ratio of the rectangular strip w/t=0.6. The resulting average efficiency of the solar collection is 64% over the collection aperture of 2B or the equivalent integrated collection efficiency of 2.06 horizontal panels. This configuration is optimized for total efficiency and also exhibits a very uniform normalized efficiency curve which is maintained between 60 and 68 percent for all solar angles from −55 degrees to +55 degrees. This configuration would offer very good collection efficiency throughout the day as well as scattered or diffuse sunlight.

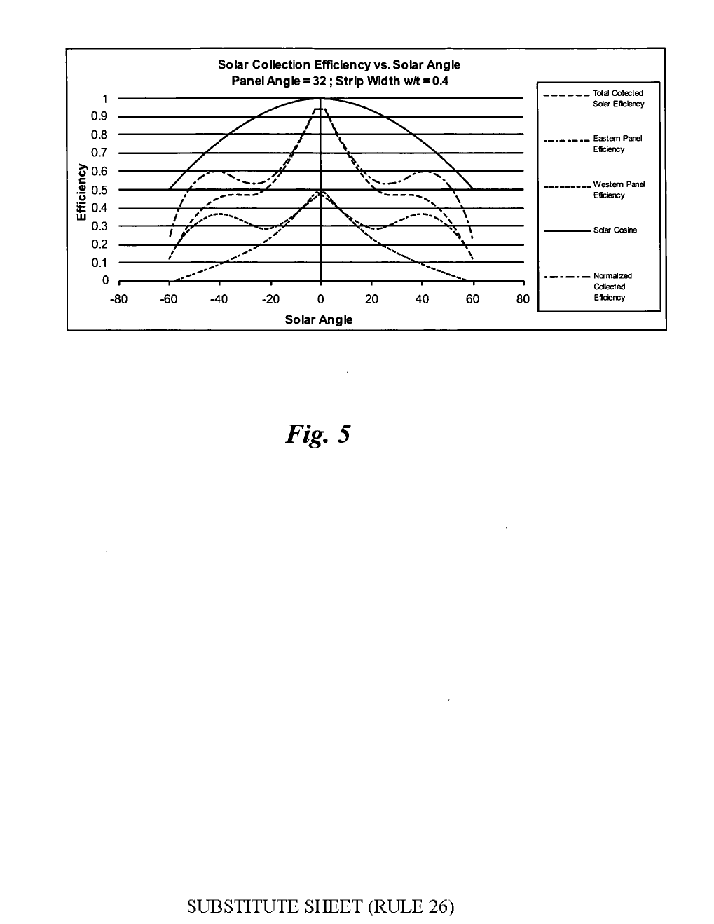

The example shown in FIG. 5 shows the result with the same panel inclination angle of η=32°, but with a narrower strip width aspect ratio of 0.4. The result exhibits higher efficiency during mid-day, when the solar angle is near zero where the efficiency reaches 95% or the equivalent of 3 horizontal panels. The efficiency drops off more rapidly as the sun angle deviates from zero, resulting in an average efficiency of 62% over the collection aperture 2B or the equivalent of 1.97 horizontal panels. Although the average efficiency is slightly lower in this case, there may be certain applications where a high peak efficiency is desirable.

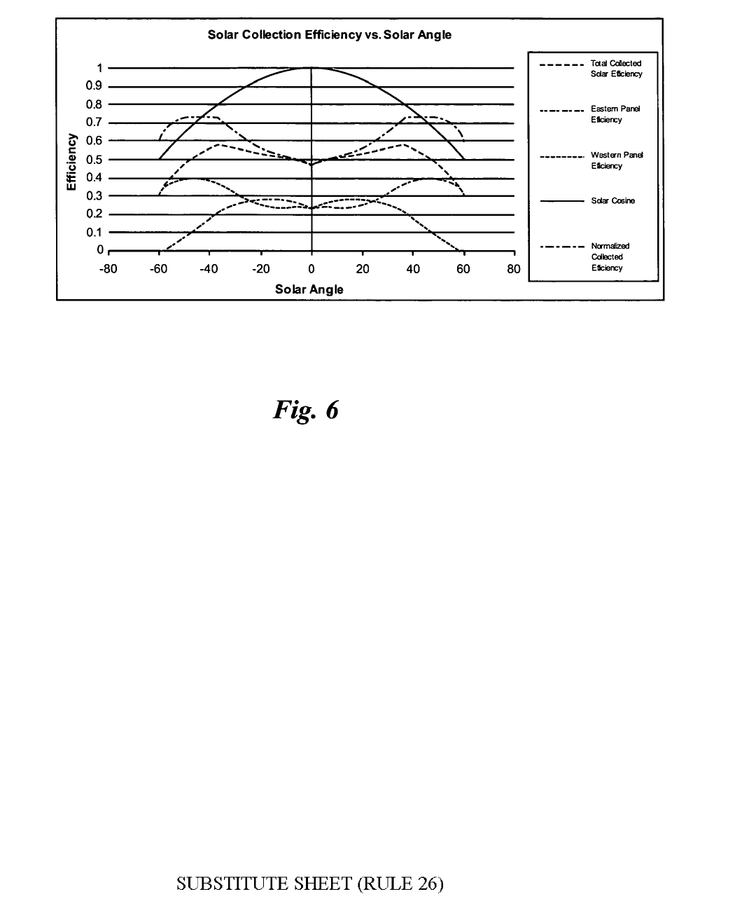

In a similar manner the configuration can be optimized for peak efficiencies during the early or late hours in the day when the sun is lower in the sky by increasing the aspect ratio of the rectangular strip cross section as shown in FIG. 6. The aspect ratio of the rectangular cross-section is 0.8 and for the same panel inclination angle θ=32°, the deflection efficiencies peak at 74% at solar angles of +/−45 degrees. The average efficiency is 62% or the equivalent of 1.97 horizontal panels.

The calculated strip width aspect ratios for both maximum integrated efficiency and maximum peak efficiency are shown in Table 1, for various panel angles. Referring to the second and third columns, the efficiency improves as the panel angle is reduced from 45 degrees, but it reaches a plateau of 2.11 effective panels at angles less than 30 degrees. Therefore, there would be diminishing benefit to reducing the angle further for the purpose of improving the total integrated efficiency.

The fourth, fifth and sixth columns show respectively the calculated strip aspect ratio corresponding to maximum center efficiency for various panel angles, the corresponding efficiency when the solar angle is zero, and the normalized total integrated efficiency at that panel angle. The preferred panel angles for such optimization are in the range of 30 to 40 degrees, where the normalized total efficiency falls within a range of 1.88 to 1.97. The relationship between the panel angle and the strip cross-section aspect ratio is noted to be very linear, with a slope equal to 0.012 per degree.

| | Strip Aspect | | Strip Aspect | Peak | |
|---|---|---|---|---|---|
| | Ratio | Eq. Panels | Ratio | Efficiency | Eq. Panels |
| Panel | @ Max | @ Max | @ Max | @ Max | @ Max |
| Angle | Av. Eff. | Av. Eff. | Peak Eff. | Peak Eff. | Peak Eff. |
| 45 | 0.57 | 1.68 | 0.54 | 1 | 1.68 |
| 44 | | | | | |
| 43 | | | | | |
| 42 | | | | | |
| 41 | | | | | |
| 40 | 0.55 | 1.87 | 0.48 | 1 | 1.87 |
| 39 | | | | | |
| 38 | | | | | |
| 37 | 0.56 | 1.97 | 0.44 | 1 | 1.94 |
| 36 | 0.55 | 1.99 | 0.43 | 1 | 1.95 |
| 35 | 0.55 | 2.01 | 0.41 | 1 | 1.96 |
| 34 | 0.56 | 2.03 | 0.4 | 1 | 1.96 |
| 33 | 0.56 | 2.05 | 0.39 | 1 | 1.96 |
| 32 | 0.57 | 2.06 | 0.38 | 1 | 1.94 |
| 31 | 0.57 | 2.07 | 0.37 | 1 | 1.93 |
| 30 | 0.58 | 2.08 | 0.35 | 1 | 1.88 |
| 29 | | | | | |
| 28 | 0.6 | 2.09 | 0.33 | 0.88 | 1.8 |
| 27 | | | | | |
| 26 | 0.61 | 2.1 | 0.31 | 0.76 | 1.72 |
| 25 | | | | | |
| 24 | 0.63 | 2.11 | 0.28 | 0.66 | 1.59 |
| 23 | | | | | |
| 22 | 0.64 | 2.11 | | | |
| 21 | | | | | |
| 20 | 0.66 | 2.11 | | | |
| 19 | | | | | |
| 18 | 0.67 | 2.1 | | | |
| 17 | | | | | |
| 16 | | | | | |
| 15 | 0.7 | 2.06 | | | |

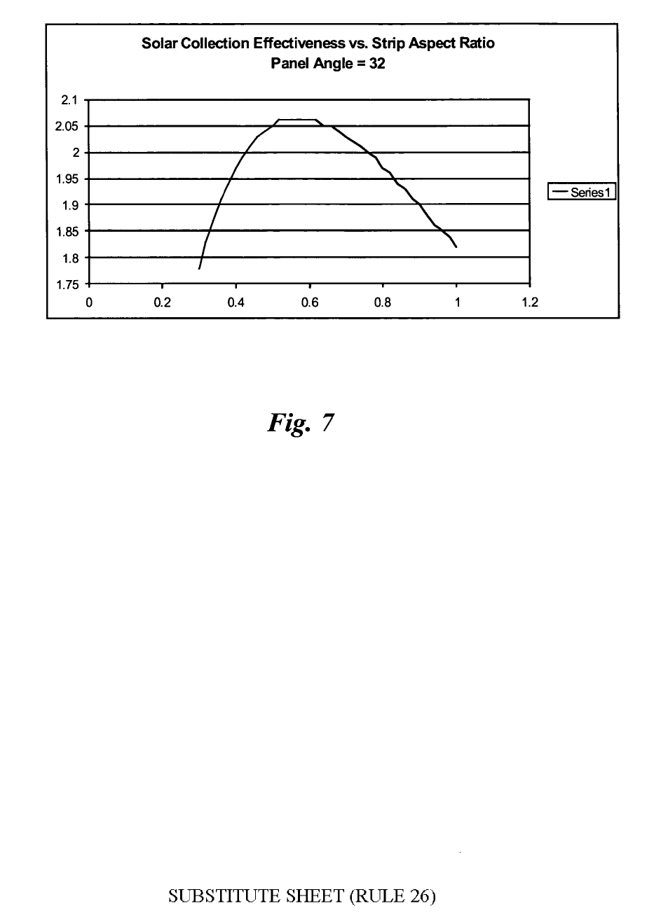

FIG. 7 shows the normalized total integrated efficiency as a function of the strip aspect ratio w/t, near the peak value for a panel angle of 32 degrees. It shows the efficiency is maintained within 1% of the peak value over a range from 0.5 to 0.65, and within 10% of the peak a range of 0.3 to nearly 1 could be used.

For steeper panel angles, the collection aperture previously defined, as 2B for the panel configuration depicted in FIG. 2 is no longer representative. When the sun is low in the sky during early morning and late afternoon hours, so that the solar angle φₛ exceeds (90−θ), the increased height of the panel configuration intercepts more sunlight than a horizontal panel of width 2B. The collection aperture equation is modified as follows:

η_{A}=cos φₛ; for |φₛ|<(90−θ) 1a.

η_{A}=cos(|φₛ|−(90−θ)/(2·cos(θ)); for |φₛ|>(90−θ) 1b.

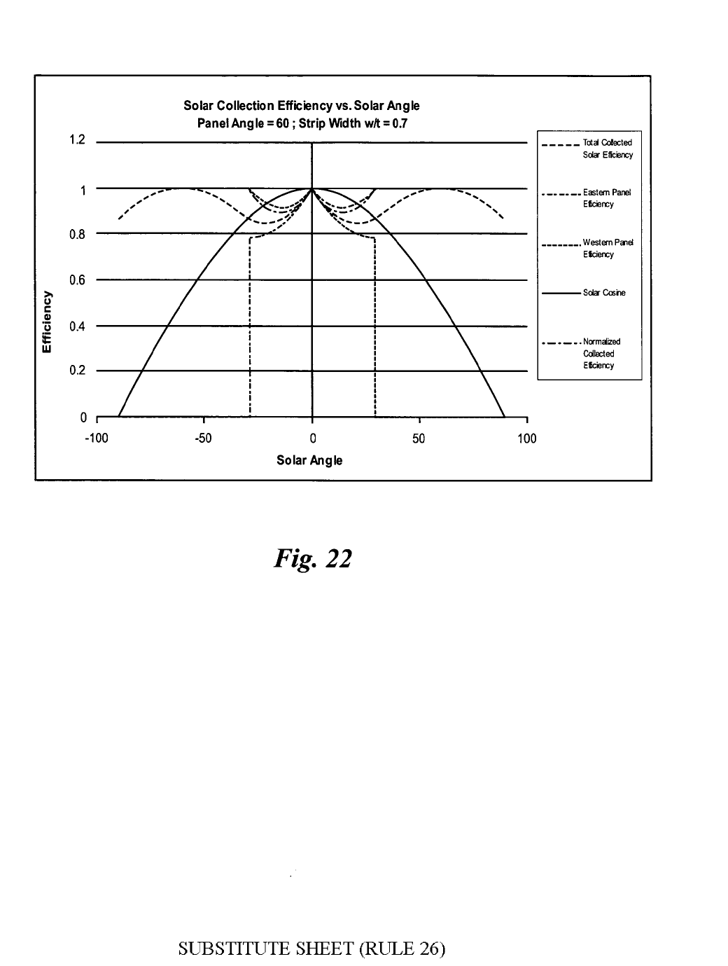

FIG. 22 shows the solar collection efficiency as a function of solar angle for θ=60° and an aspect ratio of the rectangular strip w/t=0.7 using the modified aperture equation 1a and 1b. The efficiency is 100% for solar angles exceeding 30 degrees, and then dips down to 89% at 15 degrees and back up to 99% at zero degrees. In this configuration, 47% more light is collected compared to a horizontal photovoltaic panel with the same base aperture width 2B, and the relative total integrated efficiency is the equivalent of 1.7 panels.

The analysis presented thus far has restricted the sun's movement to the equatorial plane that passes directly overhead from east to west as shown in FIG. 2. As the sun's position deviates from the equatorial plane, in and out of the page as referenced to FIG. 2, the angle of incidence of solar rays reaching the deflector panels 140 will deviate from normal in the north-south axis. Such rays will undergo a slight lateral deviation as it passes through the panel, but no angular deviation in the north-south axis will occur because the top and bottom surfaces of the deflector panels 140 are parallel and the reflecting surfaces are aligned north to south. It follows that the structure described in FIG. 2 can be oriented in any direction relative to the sun's position and the deflection of the solar rays can be resolved in two orthogonal planes relative to the deflector panels, the first in the plane of the page referenced to FIG. 2 and the second perpendicular to the plane of the page and the ground plane. In the plane of the page, the rays will deviate by reflection and refraction according to the preceding analysis, and normal to the page the rays will pass through without angular deviation.

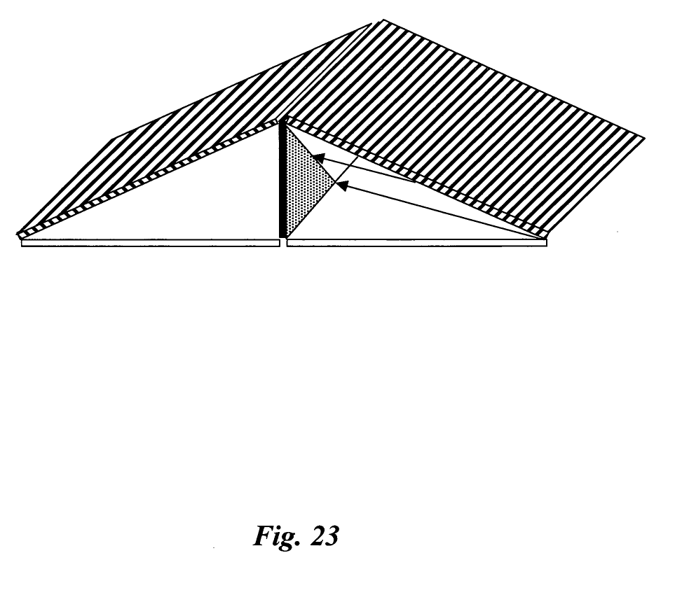

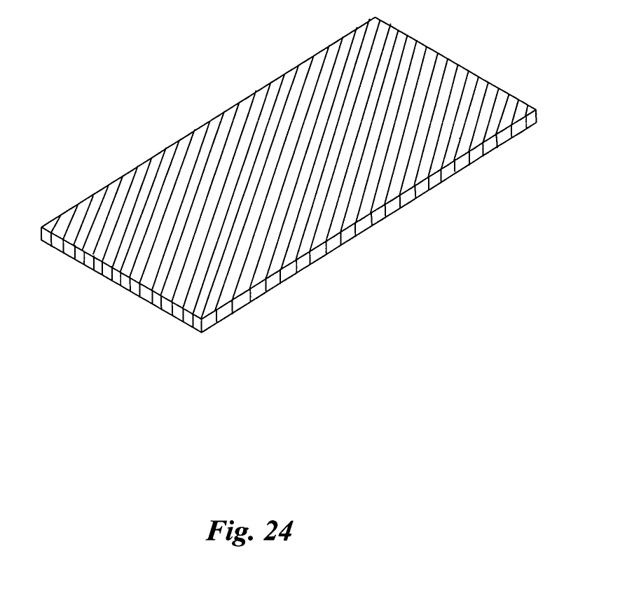

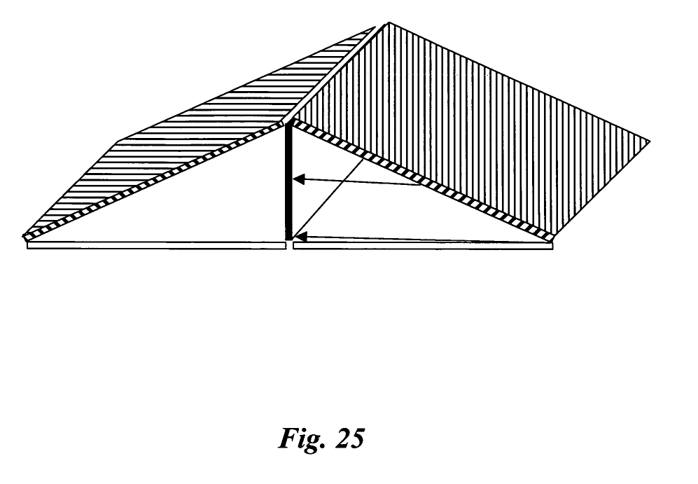

When the sun deviates from the equatorial plane, as defined by the panel configuration shown in FIG. 2, a triangular shadow is cast as shown in FIG. 23. The end of the photovoltaic panel nearest the sun is no longer fully illuminated and at the opposite end rays are lost through the open end of the structure. If long rows of panels are used the shadow effect is minimal and can be compensated by using deflector panels that overhang sufficiently at each end, or by using trapezoidal shaped deflector panels which extend the length of the outer edge away from the photo reflector panels. For short structures, particularly at high latitudes, the shadow effect can be significant. The angle of the shadow can be moderated by rotating the orientation of the reflecting strips so that they are no longer parallel with the top and bottom edge, as shown in FIG. 24. Rotating the reflecting strips at an angle equal to half of the latitude will normalize the angle of the deflected rays so that they will range between +/−23.5° seasonally, centered about zero degrees as shown in FIG. 25.

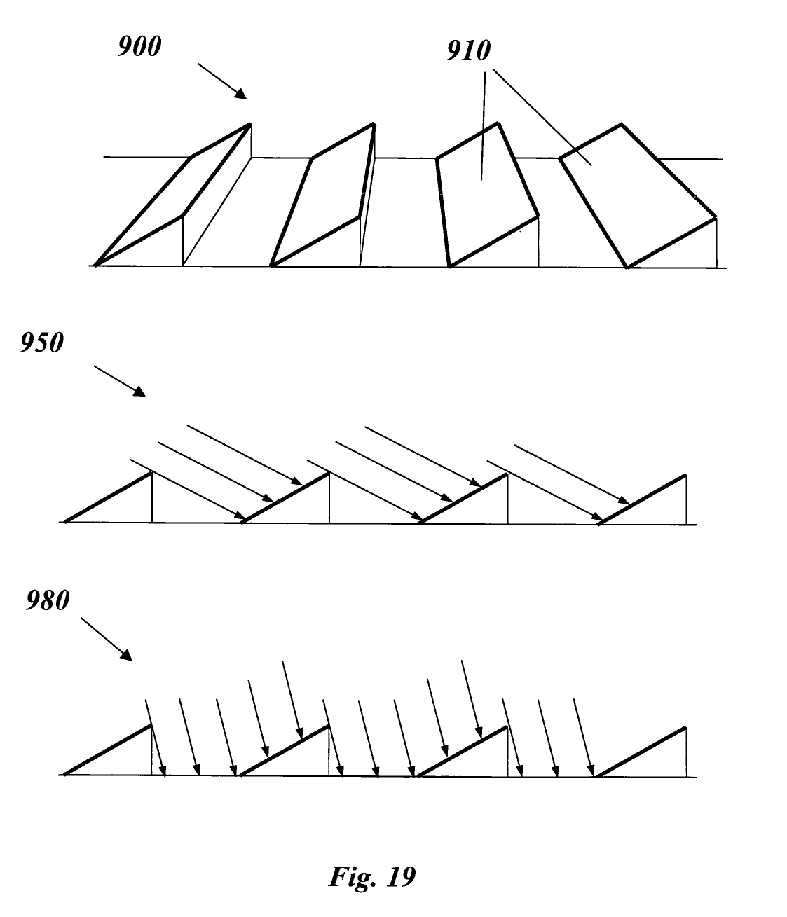

Referring now to numeral 900 in FIG. 19, an array of conventional solar panels 910 is shown as typically arranged in horizontal installations. Numeral 950 and 980 in FIG. 19 shows mid-day solar rays respectively during winter and summer extremes, corresponding to a latitude of approximately 35 degrees. At high latitudes it is advantageous to tilt solar panels 910 towards the sun, either north or south depending on the hemisphere, to maximize the use of the solar panel surface area. Ideally, the panels should be tilted at an angle equal to the latitude, however this creates a potential problem with the shadow cast between adjacent solar panels. Most photovoltaic solar panels are constructed of an array of photodiode sub-cells wired in series. If some sub-cells are not sufficiently illuminated the electrical current produced by the entire solar panel will be reduced because of increased series resistance. For this reason, sufficient space must be afforded between solar panels to avoid worst case shadow effects in winter time, as shown in numeral 950 of FIG. 19. This space represents a considerable loss in solar collection potential in summer time when the sun is high in the sky as indicated in numeral 980 of FIG. 19.

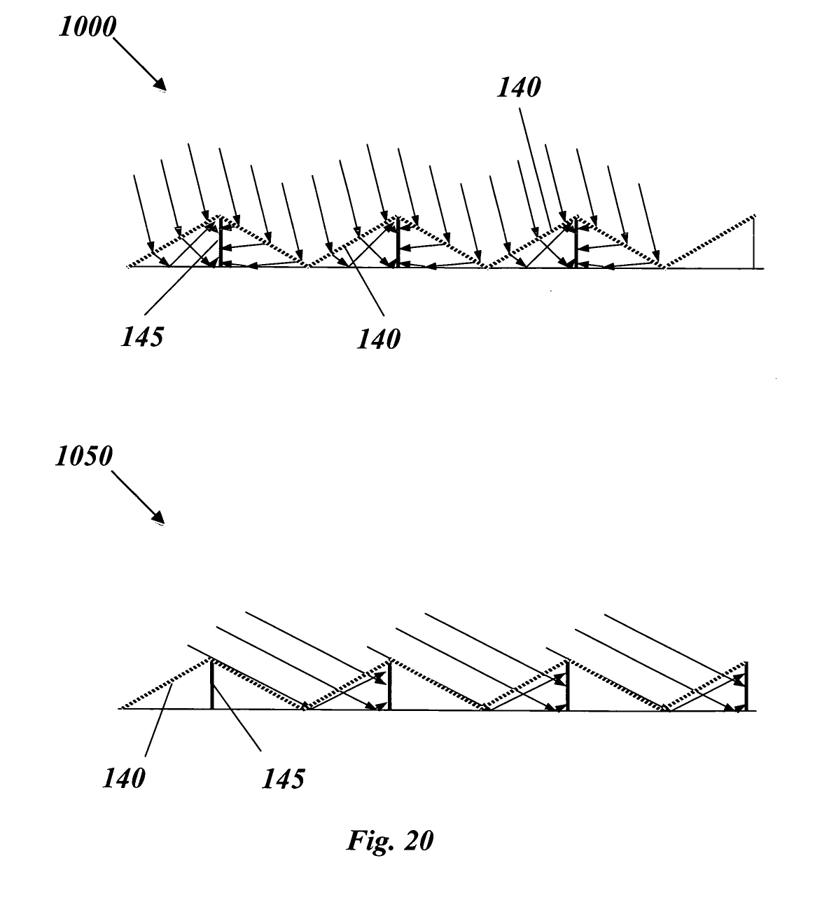

FIG. 20 shows an array of bifacial solar panel assemblies using the deflector panels 140 of the current invention along with bifacial photoreceptor panels 145 and with the peak ridge now aligned in the east-west axis. When the sun is low in the sky during winter as in numeral 1000 of FIG. 20, all of the light is shown to be incident on the sunny side deflector panels as was the case in the conventional configuration in numeral 950 of FIG. 19. When the sun is high in the sky during the summer months as shown in numeral 1050 of FIG. 20, nearly 50% of the sunlight is now incident on the shady side deflector panels 140 and is deflected on to the back-side of the bifacial photoreceptor panel 145. This represents a considerable improvement in collection efficiency when compared to the conventional case, because this sunlight was previously lost in the gap between panels.

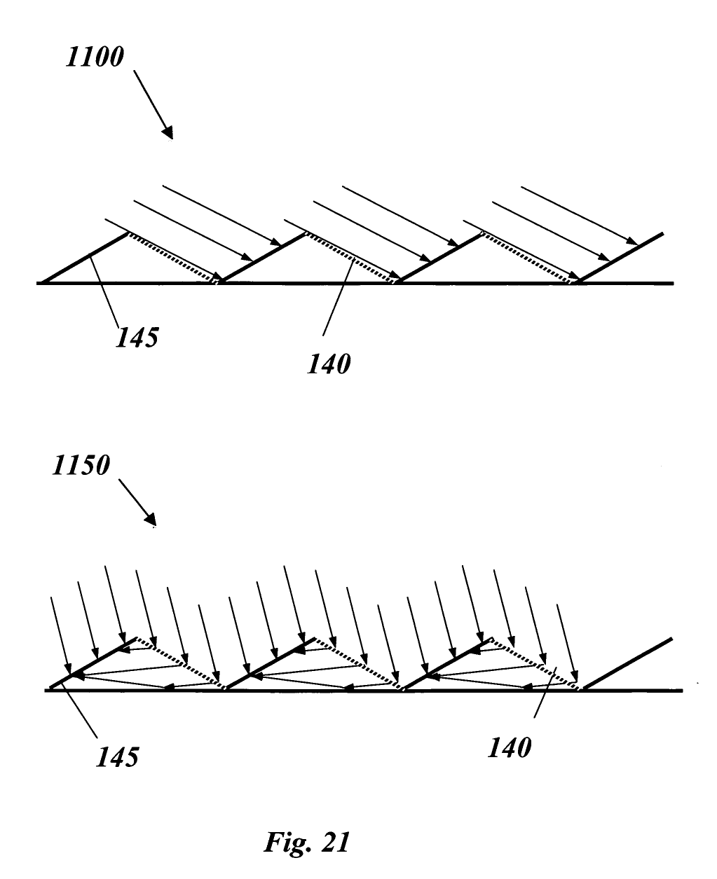

Alternatively, FIG. 21 shows a configuration of the current invention where the bifacial photoreceptor panel 145 is installed in place of the deflector panel on the sunny side of the assembly and only a single deflector panel 140 is used on the shady side. The advantage of this configuration results from the elimination of the slight transmission loss of the deflector panel on the sunny side because the sunny side of the bifacial panel is illuminated directly. The efficiency of the shady side is the same as the configuration in FIG. 20 because all of the deflected rays that would have been incident on the bifacial panel located under the peak ridge will also reach the shady side of the bifacial panel now located on the sunny side roof face. This configuration is illustrated with a low winter sun 1100 as well as a higher summer sun 1150.

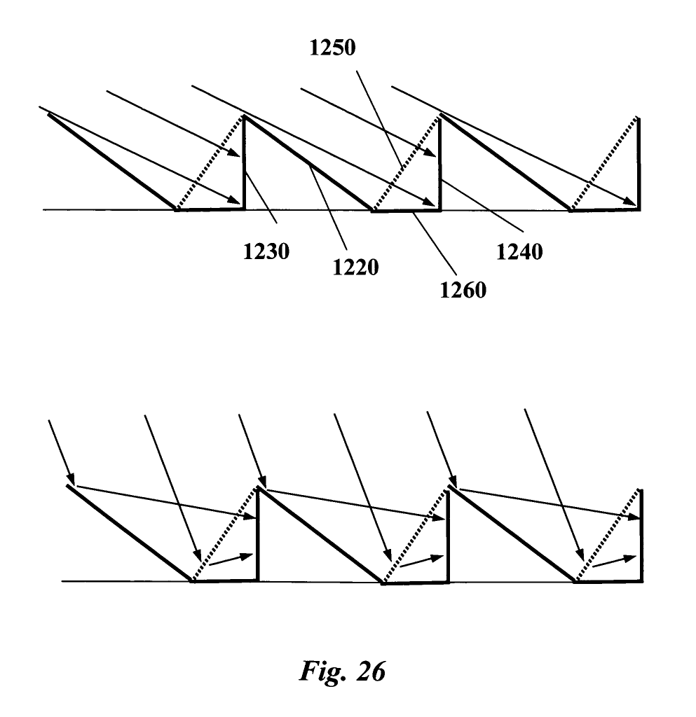

The previous examples of panel configurations have all relied on the use of bifacial photovoltaic panels. The configuration depicted in FIG. 26 shows how the deflector panel can be used with mono-facial panels. A reflector panel 1220 is positioned on the shady side of the vertical photovoltaic panel 1230 aligned on the east west axis, to reflect rays on to the photovoltaic panel 1240 of the next row. The deflector panel 1250 is held at a steeper angle and there is a second reflector panel 1260 at the base of the configuration. The distance between rows of photovoltaic panels 1230 and 1240 is set equal to the longest shadow cast on the shortest day of winter. The inclination angle of the reflector panel 1220 is set to reflect sunlight horizontally on the longest day of summer. This configuration achieves the same benefit of increased total energy collected because there are no gaps between rows, while minimizing the total surface area of photovoltaic panels.

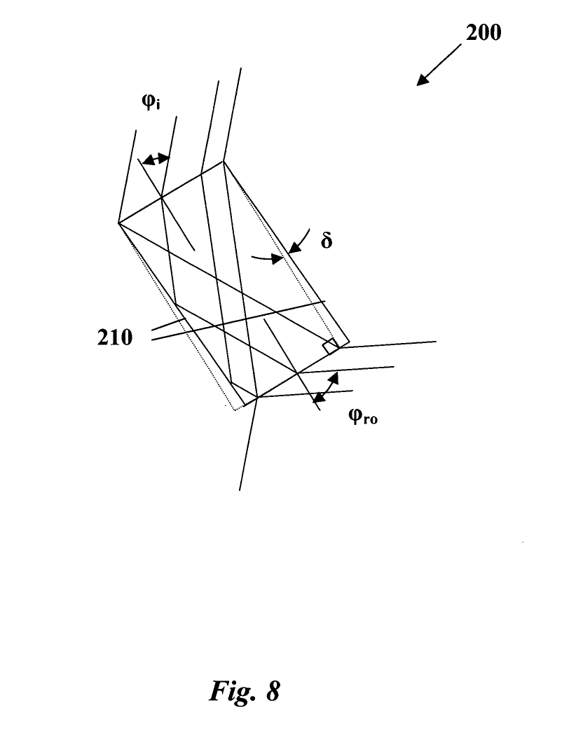

Referring now to FIG. 8, shown generally by the numeral 200, is an alternative form of the preferred embodiment comprising elongated strips with slanted side edges 210 formed by a parallelogram strip cross section. When the surface normal of each reflecting surface is tilted by an angle δ towards the direction of the sun, the reflected rays will exit the panel at an exit angle φᵣₒ greater than the angle of incidence φᵢ at the entrance side. This in effect concentrates the rays much the same as a triangular prism will concentrate light through its two refractive surfaces. The effect on solar collection efficiency can be analyzed by modifying the following equations referring to above.

(mod eq. 5)

ηₜ=(w−|(tan δ+tan φᵣᵣ))/w; for |tan φᵣᵣ|≦w−tan δ 16a.

ηₜ=0; for |tan φrr>w−tan δ 16.a

(mod eq. 8)

ηᵣ=1−ηₜ; for |tan φᵣᵣ|≦w+tan δ 17a.

φᵣ=|w/(tan φᵣᵣ−tan δ)|·(1−ηₜ); for |tan φᵣᵣ|>w+tan δ 17b.

(mod eq. 9)

φ_{rf}=φᵣᵣ+2·δ 18.

where δ is the tilt angle of the parallelogram strip cross-section.

However, because the tilted reflecting surfaces can cause the reflected ray to exceed the critical angle for total internal reflection at the exit face, an additional boundary condition must be added to equation 17 as follows:

ηᵣ=0; n·sin φ_{rf}>1 17c.

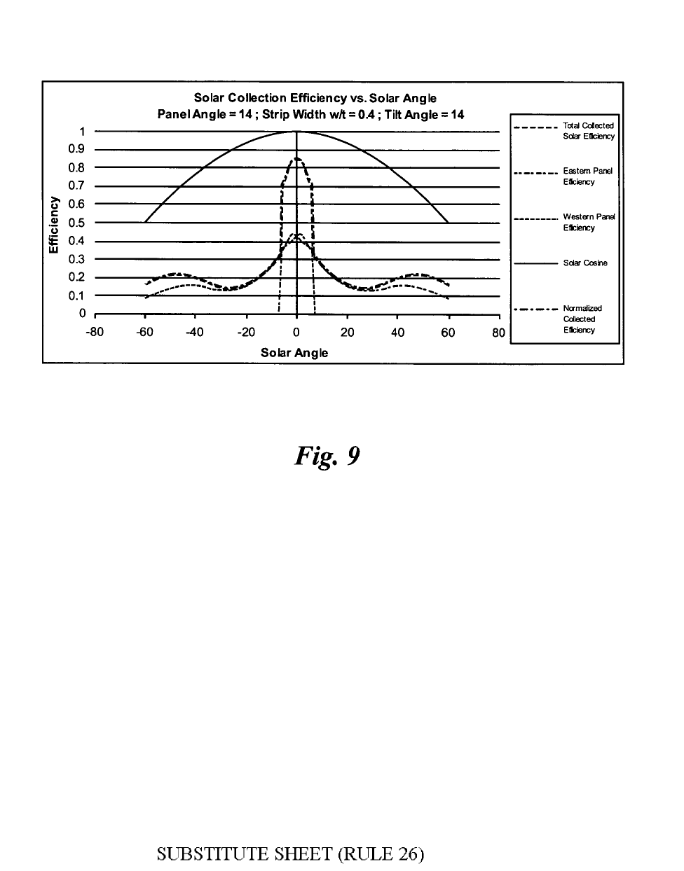

Over a large field of view, the benefit of sunlight concentration and improved efficiencies at mid day solar angles is offset by the drop in efficiency due to total internal reflection for solar angles closer to the horizon. However, tilted reflecting surfaces can be useful for certain applications where the field of view is more limited. For shallow panel angles the benefit of tilted strips for the purpose of concentrating the sunlight over a small field of view can be considerable. FIG. 9 shows an example with a panel angle of 14°, strip width aspect ratio w/t=0.4, and strip tilt angle 6 of 14°. The normalized efficiency factor is equal to 2.2 equivalent panels.

The peak efficiency is over 80%, which is the equivalent concentration factor of greater than 6.5 panels. This configuration would be suited for integration with a tracking mechanism, but would still be effective with scattered or diffuse sunlight during overcast weather.

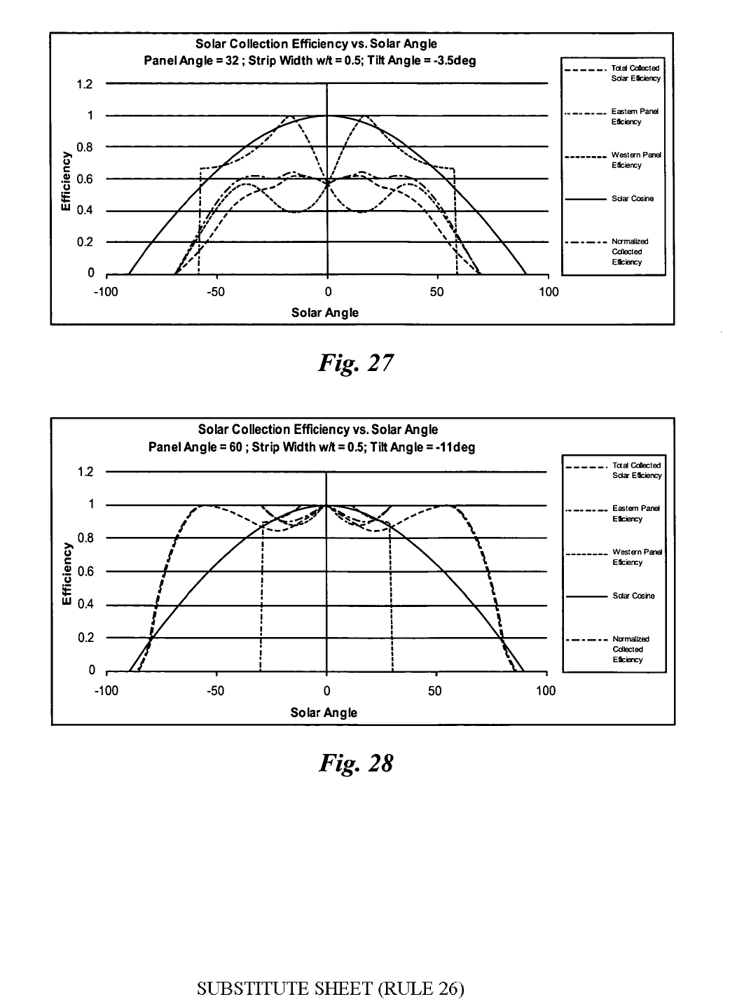

Referring back to FIG. 2 and the efficiency graphs shown in FIGS. 4 and 22, a potential shadow problem can occur on the shady side of the bifacial photovoltaic panel. If the reflected ray angle, φ_{R} exceeds 90 degrees, as is the case with the examples shown previously with non-tilted reflecting strips, then the bottom of the photovoltaic panel will not be illuminated directly. The reflecting strips can be tilted away from the sun to avoid this effect to ensure that the photovoltaic panel is always fully illuminated. FIGS. 27 and 28 show the respective graphs for panel angles of 32 and 60 degrees respectively with reflector strips tilted so that the reflected ray angle is always greater than 90 degrees. The total field of view is reduced as well as the integrated collected energy, resulting in equivalent panel ratings of 1.61 for the 32 degree case and 1.41 for the 60 degree configuration.

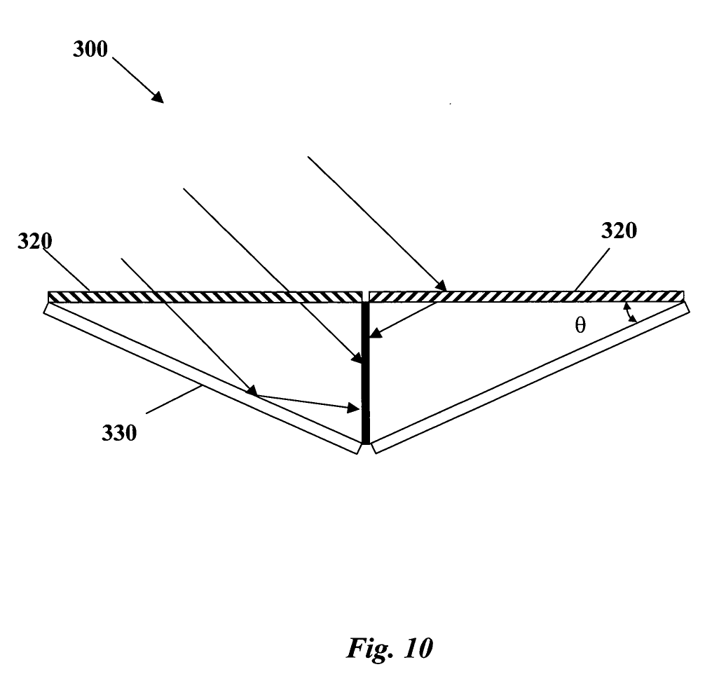

Another embodiment of the present invention is shown generally by the numeral 300 in FIG. 10. The deflector panels 320 are shown in a horizontal orientation equal to the width of the collection aperture 2B. The bottom reflector panels 330 are angled to form a right angle triangle with the photoreceptor. This configuration offers no benefit for a field of view extended from −60 degrees to +60 degrees, but if the photoreceptor panel was oriented in the east west direction instead of north south, then the required field of view to accommodate the sun's seasonal altitude movement would be reduced to +/−23 degrees.

The analysis for such a configuration requires further modification to the equations above, as follows:

)modified eq. 2)

ηᵢ =0.5 18.

(modified eq. 4)

ηₘ=0; for φ<−θ 19a.

ηₘ=sin(2(θ+φ))·sin θ/(cos φ·cos(θ+φ)) ; for −θ<φ≦0 19b.

ηₘ=sin(2(θ+φ))·sin θ/(cos φ·cos(θ+φ))−(tan θ·tan φ); for 0<φ≦90−2θ 19c.

ηₘ=1−η_{d}; for φ>90−2θ 19d.

(modified eq. 6)

φᵢ=φₛ

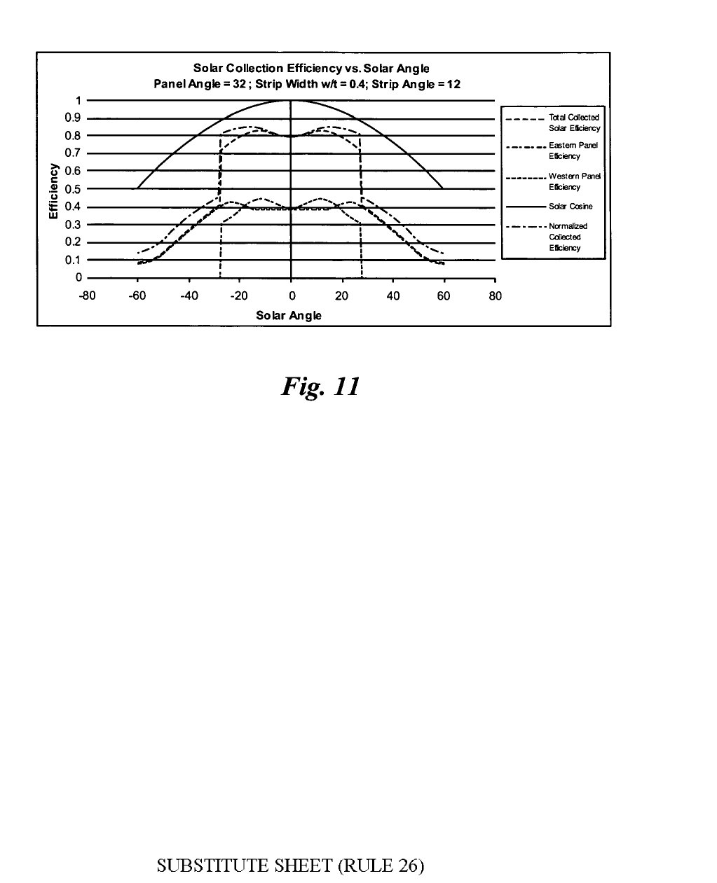

FIG. 11 shows the results for the configuration shown in FIG. 10, with a panel angle of 32 degrees, strip width aspect ratio of w/t=0.43, and a strip tilt angle δ of 13 degrees. A discontinuity in collection efficiency is shown at +/−25 degrees, indicating the point when the rays are reflected by total internal reflection from the inside panel surface. The strip angle was chosen to provide the field of view necessary to accommodate the +/−23 degrees of altitude change between seasons, and within the limits of the restricted field of view, the efficiency remains above 80%, when the sun is at its seasonal mid-point, which would result in a total integrated efficiency of 2.56 horizontal panels.

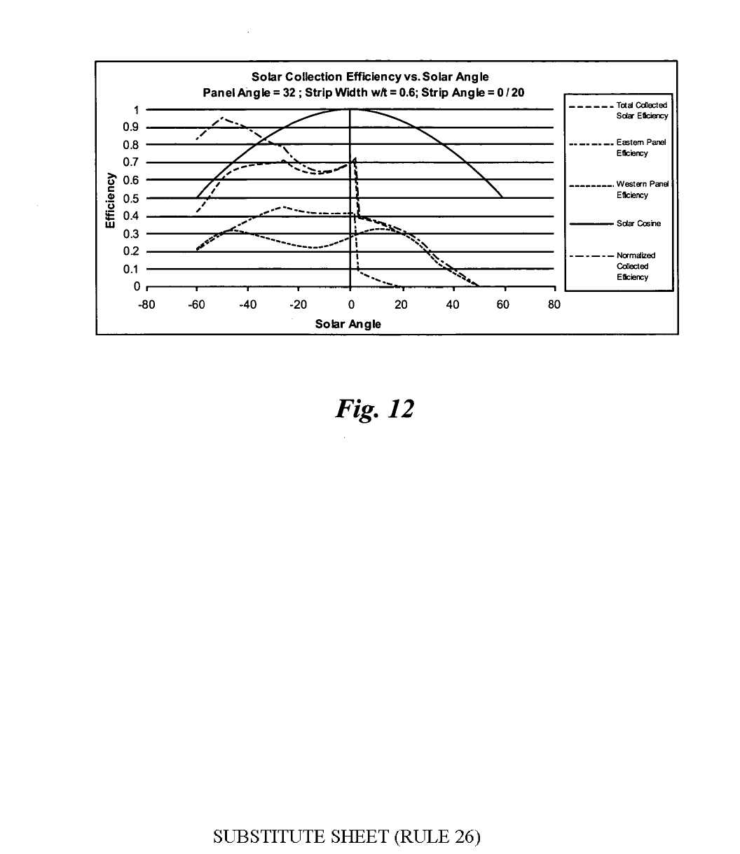

In yet another variation of the preferred embodiment, the photoreceptor panel is oriented vertical relative to the horizontal ground plane and aligned in the east west direction, but with the sun lower in the sky as would be the case in middle northern or southern latitudes. The tilt angle of the parallelogram strips is asymmetric to preferentially transmit light through the side closest the sun on to the photoreceptor and reflect light from the deflector panel on the opposite side of the photoreceptor surface. FIG. 12 shows the efficiency for an asymmetric case, with a panel angle of 32 degrees, a strip width aspect ratio of w/t=0.6 and tilt angles of zero and 20 degrees. At latitude 33 degrees, the efficiency would range from a minimum of 65% during the peak of summer, but increases to approximately 95% during the winter.

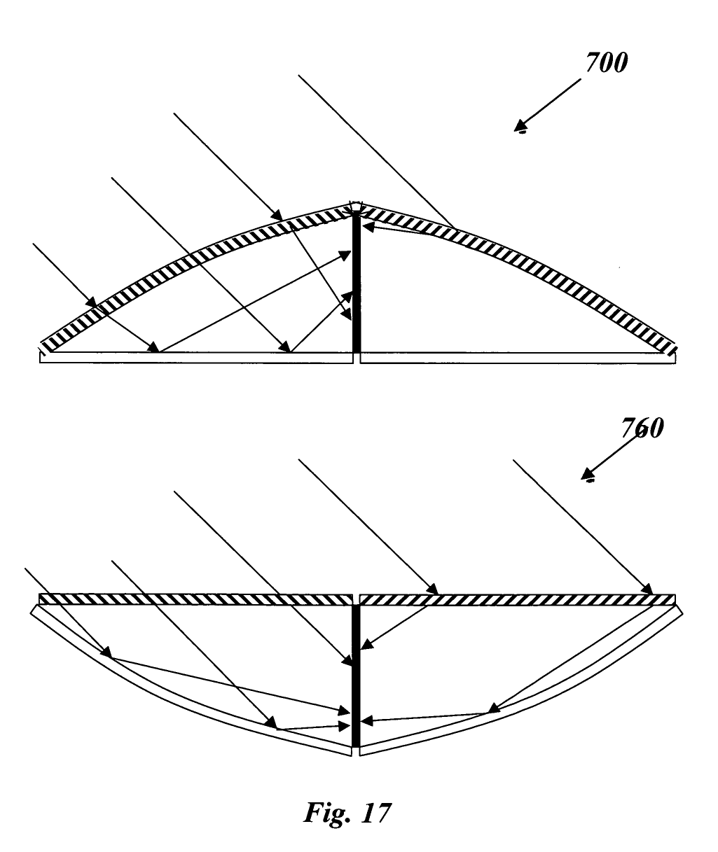

The deflector panel and/or the reflector panel can also be curved to improve the collection efficiency. FIG. 17 shows two variations, with respectively curved deflector panels 700 and curved reflector panels 760. In each case, the curved surface improves the collection efficiency of rays incident on the outer edge of the deflector panel by increasing the reflection angle. The reflection angle of rays incident near the inner edge of the deflector panel are reduced, but this can be a beneficial trade off because the angular acceptance angle is greatest near the inner edge. The net result would be to collect more sunlight from the entire deflector surface.

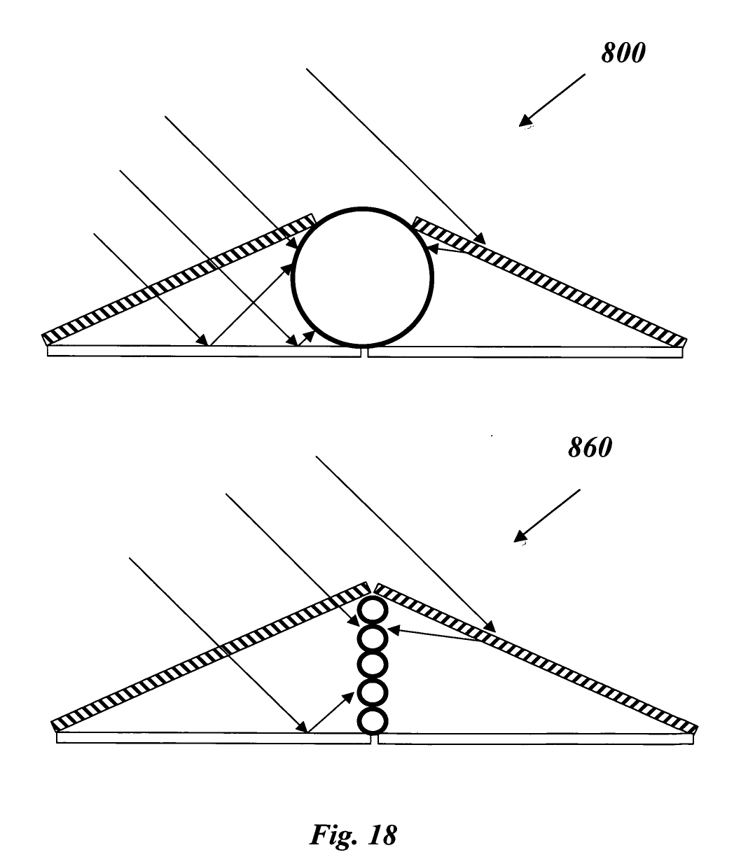

FIG. 18 shows two further embodiments of the current invention using cylindrical shaped photoreceptors. Manufacturers such as Solyndra Inc., of Fremont, Calif. have developed cylindrical photoreceptors, comprised of a photoelectric material coated on the inside of transparent tubing. The deflection of solar rays from the deflector panel and the base reflector is the same as the flat bifacial panel case. However, the collection efficiency of a cylindrical photoreceptor is improved by virtue of the larger horizontal cross section which intercepts more rays that are deflected or transmitted at near vertical angles which otherwise would have missed a flat bifacial panel. Numeral 800 of FIG. 18 shows the deflector panels extending only as far as the tangent of the cylindrical surface because there is no advantage to extending the deflector panels further to form a peak ridge. The array of smaller cylinders shown in numeral 860 of FIG. 18 would offer less benefit for improved efficiency but the configuration is suitable for thermal systems where a liquid such as water is circulated through hollow tubes.

In the above examples, the optical efficiency of the panel and the bottom mirror were set to 100%, but in real systems the reflectivity of the reflective surfaces and transmittance of the panel will be less than perfect. If good quality mirror coatings are used a reflective efficiency of 96% can be realized, and with good quality anti-reflection coatings on the front and back surface of the panel the Fresnel reflection losses can be reduced to less than 2% per surface. To include the losses in efficiency, equation 12 is modified as follows:

η_{E}=η_{A}·ηₚₜ·(ηₜ(η_{dt}·ηₘₜ)+ηᵣ·ηₚᵣ·(η_{dr}+ηₘᵣ·ηₘᵣ))
where nₚₜ, nₚᵣ, nₘᵣ are respectively the efficiency of the panel transmission, the panel reflection, and the bottom mirror reflection.

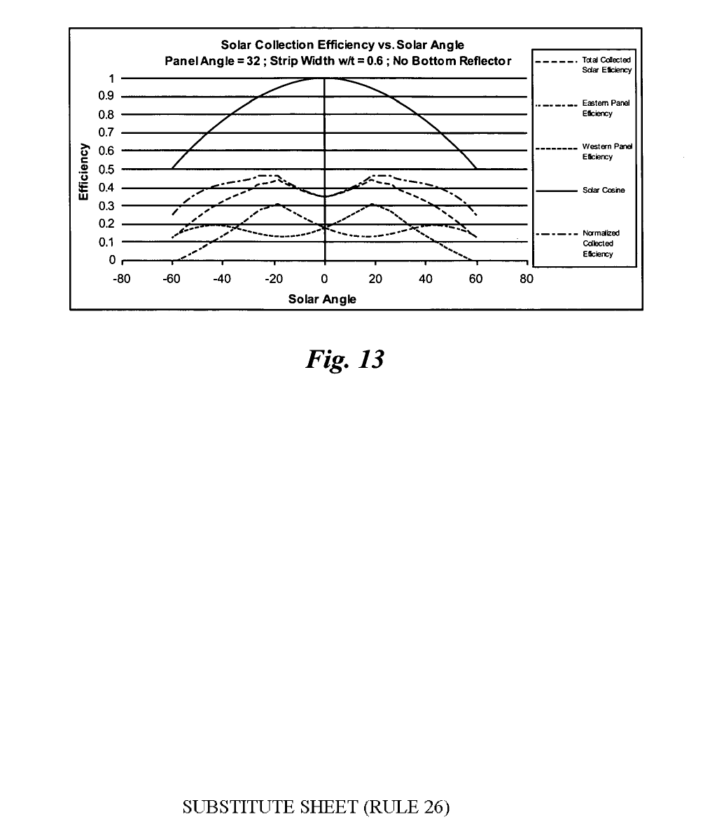

A further embodiment is the case when no bottom reflector is used, which can be analyzed by setting nₘᵣ=0. FIG. 13 shows the result with the configuration shown in FIG. 2 with η=32° and w/t=0.55, which results in a total integrated efficiency of 1.3 horizontal panels and very uniform efficiency throughout the day. This configuration could be useful for example with greenhouses, where bifacial panels could be hung from the roof apex and the deflector panels of the present invention used for the roof panels. In addition to the energy production generated by the photovoltaic panel, for morning and afternoon sun, a portion of the sunlight will be reflected downward toward the floor which otherwise would be pass over the crops.

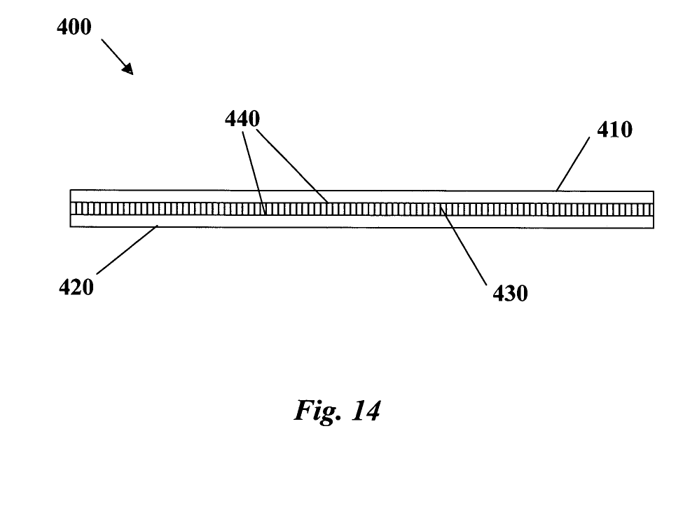

Considering now the construction of the deflector panel, FIG. 14, shown generally by the numeral 400, shows a cross-section of a portion of the deflector panel, with two laminations of plane sheets of transparent material 410 and 420 sandwiching the rectangular strip array layer in the middle. The optical performance of the deflector panel is unaffected by adding the laminations, but could be advantageous to add strength to the overall structure. Furthermore, presuming that all the material used is matched in refractive index, including the adhesive layers 440 imperfections in the top and bottom surfaces or filling with a conforming material could repair vertices of the rectangular strips.

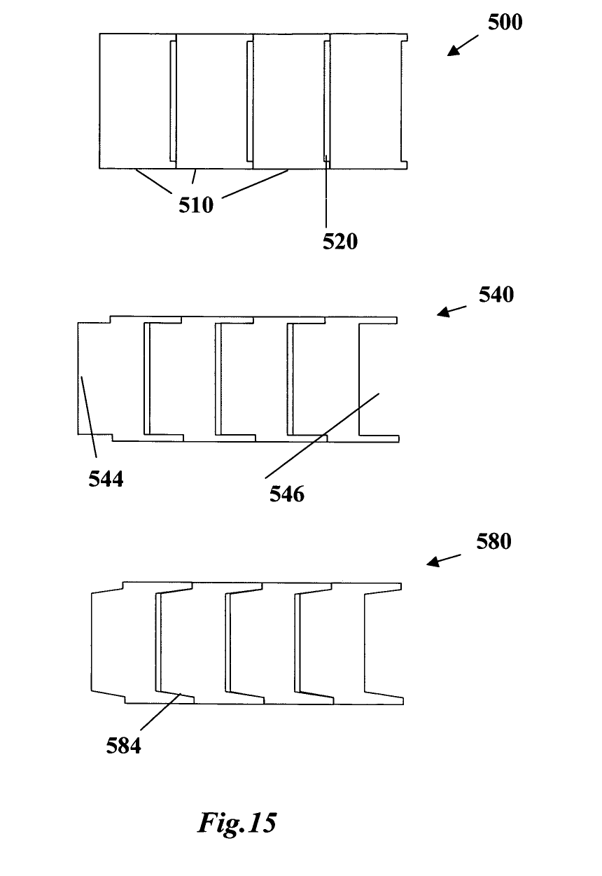

The deflector panel may also be constructed from alternative strip profiles that may incorporate other beneficial features such as shown in FIG. 15. The numeral 500 in FIG. 15 shows a cross-section of a portion of the deflector panel where the rectangular strips 510 are modified by introducing a recess 520 on part of one side of the spaced planar reflecting surfaces. When an array of identical strips is joined together, a small gap is maintained between strips that would create a total internal reflecting surface without the need for mirror coating. Numeral 540 shows a modification of this concept with an interlocking ridge 544 and recess 546 on opposite sides of the strip that can be used to separate the bonded surfaces from the gap. Finally, numeral 580 shows a further modification with beveled ridge and recess edges 584 that could make the interlocking easier to assemble.

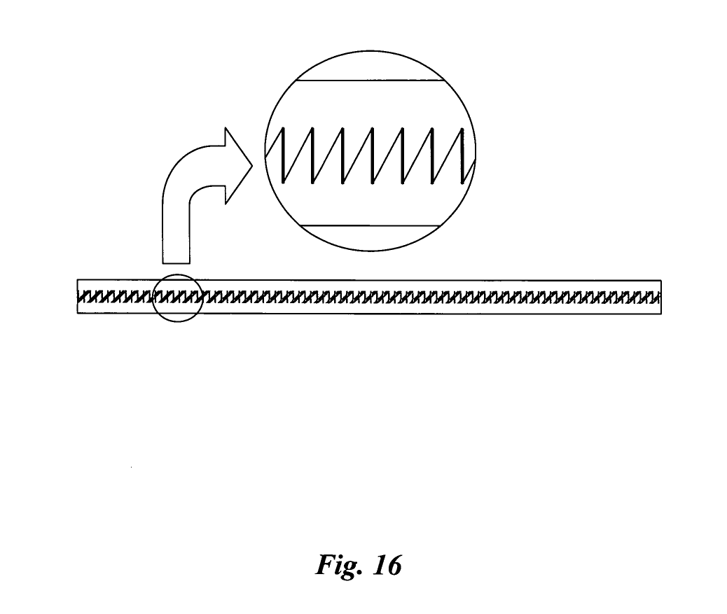

As an alternative to assembling multiple strips, FIG. 16 shows the deflector panel comprised of two identical sheets of plastic mated together. An array of identical linear saw-tooth profile ridge prisms is molded into the surface of one of the sides of each sheet such that when the two sheets are bonded together the saw-tooth ridges interlock to form a solid structure. A mirror coating is applied to the vertical surface of each saw-tooth ridge before mating the sheets together. An index-matching adhesive is used to bond the sheets so that the optical boundary between the uncoated ridge surfaces disappears. This approach can significantly reduce the assembly complexity. The saw-tooth ridge structures can be fabricated by standard techniques of compression molding, or injection molding, or rolling with an engraved cylinder, as is used to make large format Fresnel lenses and lenticular screens.

Yet another construction method of the deflector panel would be to cast the panel with embedded thin double-sided reflector strips. The reflector strips could be made from mirror coated polymer strips and held temporarily during the casting process. The casting material could be a UV set polymer resin.

While the present invention has been described in some detail, according to the preferred embodiments illustrated above, it is not meant to be limiting to modifications such as would be obvious to those skilled in the art.

1. A solar deflector panel assembly for directing sunlight on to a photoreceptor surface comprising;
an approximately rectangular solar deflector panel constructed of a transparent material and having a length L, a width W, a top surface, a bottom surface, and an inner and outer edge along length L;
an array of spaced planar reflecting surfaces extending over the length L of said solar deflector panel substantially parallel to said inner and outer edges, said planer planar reflecting surfaces being substantially perpendicular to said top and bottom surfaces;
an approximately rectangular photoreceptor surface having a top edge and a bottom edge positioned so the top edge of said photoreceptor surface is oriented towards the sky and the bottom edge oriented towards the ground; and
wherein said solar deflector panel, is positioned so that the inner edge is held in proximity and approximately level with the top edge of said photoreceptor surface and the outer edge of said solar deflector panel is extended away from said photoreceptor surface.

2. The solar deflector panel assembly of claim 1 further comprising; an approximately rectangular reflector panel positioned between said bottom edge of said photoreceptor surface and said outer edge of said solar deflector panel.

3. The solar deflector panel assembly of claim 1, wherein said solar deflector panel is constructed of a stack of identical elongated strips of transparent material, each strip with parallel top and bottom surfaces and two opposing parallel reflective side surfaces substantially perpendicular to the top and bottom surface, affixed together with the top and bottom surfaces of the elongated strips forming flat top and bottom surfaces of said deflector panel.

4. The solar deflector panel assembly of claim 1, wherein the ratio of spacing between said spaced planar reflecting surfaces relative to a height of said spaced planar reflecting surfaces falls within a range of 0.3 to 1.00.

5. The solar deflector panel assembly of claim 4, wherein the ratio of spacing between said spaced planar reflecting surfaces relative to the height of said spaced planar reflecting surfaces falls within a range of 0.4 to 0.7.

6. The solar deflector panel assembly of claim 5, wherein the ratio of spacing between said spaced planar reflecting surfaces relative to the height of said spaced planar reflecting surfaces falls within a range of 0.50 to 0.65.

7. The solar deflector panel assembly of claim 1 wherein said spaced planar reflective surfaces have metallic or dielectric coatings.

8. The solar deflector panel assembly of claim 1 wherein said transparent material has a refractive index of greater than 1.414 and said reflecting surfaces are achieved by total internal reflection by providing a small gap between said spaced planar reflecting surfaces.

9. The solar deflector panel assembly of claim 3 wherein separate top and/or bottom sheets of transparent material are laminated and affixed to the stack of said elongated strips.

10. The solar deflector panel assembly of claim 1, wherein said photoreceptor surface is bifacial and an additional approximately rectangular solar deflector panel is disposed on the opposite side of said photoreceptor surface, positioned so that the inner edge is held in proximity and approximately level with the top edge of said photoreceptor surface and the outer edge of said additional approximately rectangular solar deflector panel is extended downward and away from said photoreceptor surface.

11. The solar deflector panel assembly of claim 10 further comprising an additional approximately rectangular reflector panel disposed on each side of said photoreceptor surface, and positioned between said bottom edge of said photoreceptor surface and said outer edges of said solar deflector panels.

12. The solar deflector panel assembly of claim 1 wherein said array of spaced planar reflecting surfaces are tilted with respect to the surface normal of said top surface and said bottom surface of said solar deflector panel.

13. The solar deflector panel assembly of claim 12 further comprising an approximately rectangular reflector panel positioned between said bottom edge of said photoreceptor surface and said outer edge of said solar deflector panel.

14. The solar deflector panel assembly of claim 12, wherein said photoreceptor surface is bifacial and an additional approximately rectangular solar deflector panel is disposed on the opposite side of said photoreceptor surface, positioned so that the inner edge is held in proximity and approximately level with the top edge of said photoreceptor surface and the outer edge of said additional approximately rectangular solar deflector panel is extended downward and away from said photoreceptor surface.

15. The solar deflector panel assembly of claim 14 further comprising an additional approximately rectangular reflector panel disposed on each side of said photoreceptor surface, and positioned between said bottom edge of said photoreceptor surface and said outer edges of said solar deflector panels.

16. (canceled)

17. The solar deflector panel assembly according to claim 1 wherein said approximately rectangular photoreceptor surface is replaced by a vertical array one or more of cylindrical photoreceptor surfaces.

18. The solar deflector panel assembly according to claim 1 wherein said array of spaced planar reflecting surfaces of said solar deflector panel intersect said inner and outer edges.

19. The solar deflector panel assembly according to claim 1 wherein said approximately rectangular deflector panel is curved along width W.

20. The solar deflector panel assembly according to claim 2 further comprising an additional approximately rectangular reflector panel with an inner edge and an outer edge, with inner edge of said additional reflector panel disposed near outer edge of said deflector panel and outer edge of said additional reflector panel extending outward and upward from said deflector panel.

21. The solar deflector panel assembly according to claim 12 wherein said array of spaced planar reflecting surfaces of said solar deflector panel intersect said inner and outer edges.

22. The solar deflector panel assembly according to claim 12 wherein said approximately rectangular deflector panel is curved along width W.

23. The solar deflector panel assembly according to claim 12 wherein said approximately rectangular photoreceptor surface is replaced by a vertical array of one or more cylindrical photoreceptor surfaces.

24. The solar deflector panel assembly according to claim 12 further comprising an additional approximately rectangular reflector panel with an inner edge and an outer edge, with inner edge of said additional reflector panel disposed near outer edge of said deflector panel and outer edge of said additional reflector panel extending outward and upward from said deflector panel.
